(19) United States
(12) Patent Application Publication
(10) Pub. No.: US 2006/0157684 A1
(43) Pub. Date: Jul. 20, 2006

(54) Thin film multilayer with nanolayers addressable from the macroscale

(75) Inventor: Derek Decker, Byron, CA (US)

Correspondence Address: Assistant Laboratory Counsel;Lawrence Livermore National Laboratory, L-703, P.O. Box 808, Livermore, CA, 94551, US

(73) Assignee: The Regents of the University of California

(21) Appl. No.: 11/303,495

(22) Filed: Dec. 15, 2005

Related U.S. Application Data
(60) Provisional application No. 60/637,372, filed on Dec. 15, 2004.

(51) Int. Cl. H01L 29/06

(52) U.S. Cl. 257/13

(57) ABSTRACT

A thin film multilayer device having a multilayer stack formation including an array of electrically conductive or optically transmissive nanolayers separated by insulating layers. The nanolayers have one end with nanometer size and spacing, and another end with macro-sized tab sections through which the array of nanolayers may be individually addressed from the macro regime. In this manner, a spatial field (including analytes present in the field) adjacent the nanoscale ends of the array may be directly sensed and/or controlled at the nanometer level. The thin film multilayer device may be fabricated, for example, using thin film deposition techniques. In one embodiment, a spatially manipulable slotted mask or masks is used to vary the spatial position of the tab sections while maintaining an overlap in other sections to form the stack. Upon stack formation, a cross-sectional surface is exposed, such as by cleaving, to reveal nanoscale edges of the nanolayer array separated by the insulating layers. The nanoscale edges act as finely spaced wires for use in moving, energizing, exciting, assembling, detecting, or otherwise sensing and/or controlling objects on or near the surface, for such example applications as real time imaging of cellular activity and controlled interactions betweens molecules.

### I. CLAIM OF PRIORITY IN PROVISIONAL APPLICATION

This application claims the benefit of U.S. provisional application No. 60/637,372 filed Dec. 15, 2004, entitled, “Construction of Microscopic Conductors and Means of Macroscopic Attachment Thereto” by Derek E. Decker.

The United States Government has rights in this invention pursuant to Contract No. W-7405-ENG-48 between the United States Department of Energy and the University of California for the operation of Lawrence Livermore National Laboratory.

### II. FIELD OF THE INVENTION

The present invention is directed to thin film multilayers and fabrication methods. More particularly the present invention relates to a thin film multilayer device and fabrication method having macroscopic interconnection tabs by which nanoscale edges of addressable nanolayers are addressed individually or in combination with others so as to detect, monitor, move, manipulate, modify, assemble, align, or otherwise sense and/or control nanoscale objects, devices, cells, molecules, spatial field, etc. from the macroscale regime.

### III. BACKGROUND OF THE INVENTION

Developments in fabrication technology have enabled and improved the fabrication of nano devices and machines. Multilayer coating methods, for example, have improved dramatically over the last twenty years to enable single layer depositions in the nanoscale and even atomic scale regimes, using for example such techniques as molecular beam epitaxy (MBE), chemical vapor deposition (CVD), and self assembly which can be done in a fluidic environment. Such fabricated multilayers typically have superior properties (e.g. extremely smooth and thin layers) and are often used, for example, for high performance optical filters and reflectors even into the 10 nm soft x-ray or Extreme Ultraviolet (EUV) region. Unique optical and electronic properties are also obtained with such a multilayer superlattice and are exploited in various electronic and optoelectronic devices. Unfortunately, there is an operational gap between the nanoscale regime and our macro world of conventional machines and methods. Thus the challenge has been to provide a macroscopic connection/interface to such nanoscale devices, in order to directly sense and/or exert control in the nano regime.

Complex molecules can also be thought of as nano sized machines which act on other atoms and molecules. For example, catalysts may be characterized as miniature and efficient assembly lines or machines which take in one or more components and output one or more desired products at an accelerated rate when compared to non-catalytic reactions. However, the ability to grab a single molecule, manipulate it, and watch it perform chemistry at the atomic level is still severely limited. Atomic Force Microscopes (AFMs), for example, are good for atomic level surface topography and some additional probing into macromolecules using more sophisticated techniques. However, AFMs are a single point contact which has limited ability to manipulate and monitor molecules.

What is needed therefore is a nanoscale device capable of sensing and/or controlling at the nanoscale level/resolution but addressable from the macroscale regime. In particular, it would be advantageous to control electrostatic forces at the nanometer level/resolution with an array of addressable conductors on a surface. The ability to control in the nanoscale regime could enable a wide range of applications, including for example using these forces to bring molecules together and then try to pull them apart in order to assess the binding forces between them. Also it would be advantageous to provide a nanoscale device cable of detecting direct current resistance and alternating current impedance characteristics of unknown materials between electrodes at the nanometer level. These and other pulsed techniques can reveal dielectric constants, transient response, decay rates, polarizability, florescence and birefringence, among other material properties. A device which also enables the monitoring of the nanoscale materials in real time and high resolution is also needed, such as for example to track the movement and chemical changes as various molecules interact within cells or other environments.

### IV. SUMMARY OF THE INVENTION

One aspect of the present invention includes a method of fabricating a thin film multilayer device, comprising: forming a multilayer stack having a substrate, at least one addressable nanolayer, and at least one insulating layer, said stack forming step including forming each addressable nanolayer with at least one tab section extending out from the multilayer stack with a greater-than-nanoscale surface area; and exposing a cross-sectional surface of the multilayer stack including a nanoscale edge of each addressable nanolayer, whereby a spatial field adjacent the exposed cross-sectional surface may be sensed and/or controlled by the nanolayer edge(s) in the nanoscale regime when addressed from a greater-than-nanoscale regime via the corresponding tab section(s).

Another aspect of the present invention includes a thin film device comprising: a thin film multilayer stack having a substrate, at least one addressable nanolayer, and at least one insulating layer, each addressable nanolayer having at least one tab section extending out from the multilayer stack with a greater-than-nanoscale surface area, and said multilayer stack having a cross-sectional surface exposing a nanoscale edge of each addressable nanolayer, whereby a spatial field adjacent the cross-sectional surface may be sensed and/or controlled by the nanoscale edge(s) in the nanoscale regime when addressed in the greater-than-nanoscale regime via the corresponding tab section(s).

Another aspect of the present invention includes a thin film system comprising: first and second thin film multilayer stacks, each having a substrate, at least one addressable nanolayer, and at least one insulating layer, with each addressable nanolayer having at least one tab section extending out from the corresponding multilayer stack with a greater-than-nanoscale surface area, and each multilayer stack having a cross-sectional surface exposing a nanoscale edge of each addressable nanolayer thereof, said cross-sectional surfaces being spaced from each other to form a spatial field therebetween and arranged skew to each other so that the nanoscale edges of the first cross-sectional surface intersect the nanoscale edges of the second cross-sectional surface when projected across the spatial field, whereby regions of the spatial field corresponding to the projected intersections may be sensed and/or controlled by the nanoscale edges in the nanoscale regime when addressed in the greater-than-nanoscale regime via the corresponding tab sections.

The present invention is directed to a thin film multilayer device having an array of addressable nanolayer pathways which at one end are on the order of nanometers in size (i.e. thickness) and spacing, and at an opposite end have tab sections with large, greater-than-nanoscale (e.g. microns to millimeters or larger) surface areas which enable external electrical or optical interconnections to be made. In this manner, the thin film multilayer device serves as a nano-macro interface to allow ultra-high resolution sensing, scanning and/or control at the nanoscale level/resolution from the macro world, and which makes possible, for example, real time imaging of cellular activity and controlled interactions betweens objects, including large molecules.

Generally, the thin film multilayer device has at least one addressable nanolayer and at least one insulating layer formed on a substrate to form a multilayer stack (i.e. the overlapping sections of the addressable nanolayers and insulating layers). Additionally, the thin film multilayer device has an exposed cross-sectional surface revealing each of the nanolayers along a nanoscale edge. Preferably, a plurality of addressable nanolayers and insulating layers form the multilayer stack, and are preferably arranged in alternating order so that the insulating layers insulate the addressable nanolayers, especially from each other. Each nanolayer of the array may be individually addressable or configured to be addressable together with other nanolayers in a predetermined group. And each addressable nanolayer has at least one tab section which extends out from the multilayer stack to serve as a connector port. The tab sections may extend out (protrude) from the stack in any direction, such as extending radially outward from an overlapping center section or radially inward from an overlapping peripheral section, so long as the tab section has a greater-than-nanoscale surface area to allow connection or porting by a macro interconnect, such as wire solder. For example, the tab sections may be greater than 200 nm by 200 nm in size. Multiple tab sections may be formed for each addressable nanolayer, either to provide multiple access ports to the nanolayer of a single device, or as an intermediate fabrication step where a single multilayer stack is divided into multiple unit devices, each having at least one tab section.

It is appreciated that the term “nanoscale” as used herein and in the claims, includes the range less than 1000 nm. Therefore, a nanolayer is a thin film layer having nanoscale thickness, which in a preferred embodiment is less than 100 nm. And as used herein and in the claims, the terms “greater-than-nanoscale,” and “macroscale” encompass all size ranges greater than the nanoscale, including micro, milli, and larger size ranges. And as used herein and in the claims, “addressable” is the quality of being accessible through an address. In the present invention, the addressable nanolayers enable access to a desired one or more of the nanoscale edges along the cross-sectional surface of the multilayer stack from the macro regime via the greater-than-nanoscale tab sections, which enables the direct sensing and/or control of the nanoscale edges from the macro regime. The particular mode for sensing and/or controlling can be by electrical conduction, optical transmission, or other physical transfer mode (e.g. acoustic or thermal conduction). Thus, in preferred embodiments, the addressable nanolayers are either an electrically conductive material known in the art, such as gold, to make the nanolayer electrically addressable, or an optically transmissive material known in the art, such as SiO₂, to make the nanolayer optically addressable. It is also appreciated that the term “insulating” layer encompasses materials which electrically, optically, or even thermally or acoustically insulate as appropriate, depending on the type of addressable nanolayer used. Thus, for example, where optically addressable nanolayers are used in the stack, optically insulating layers may be used to isolate the nanolayers, especially from each other. Various methods of optical isolation are known in the art, such as the use of lower index cladding materials or reflective cladding (metallic or photonic materials or absorbing or a combination of these).

The invention is also directed to a fabrication method of such a thin film device described above. Generally, a multilayer stack of the thin film device is first fabricated, preferably by using thin film deposition techniques, such as vapor deposition, or heavily doping a semiconductor or other substrate. Thin film deposition processes include, for example, sputter deposition, optical lithography patterning with subsequent doping, masking of ion implantation, optical surface processing, spin coating, and others. Other methods include combining lithographic techniques with self assembling monolayers of conducting molecules and/or conducting nanospheres. Linker molecules can be designed to be conductive and selective in bonding just to the surface and not to each other. This limits growth beyond a single layer while achieving good coverage of the surface. An insulating layer (e.g. non-conductive layer, or optical cladding) may be deposited atop the addressable nanolayer in similar ways, including vapor deposition of polymers, growing amorphous silicon, and self assembly. Preferably, the addressable layers are deposited using a spatially-controllable mask. A slot aperture of the mask may be reoriented after each nanolayer deposition through the aperture, in order to form overlapping sections while keeping the tab sections from overlapping each other. In the alternative, a plurality of masks having spatially-differentiated patterns may be used to achieve the same.

After the multilayer stack is formed, a cross-sectional surface of the stack is exposed by a material removal process, such as cutting or cleaving the stack, and/or polishing, and/or etching. Other methods for removing material (such as drilling) may alternatively or additionally be used to form the cross-sectional surface. In any case, the exposed cross-sectional surface reveals the nanoscale edges of the array of addressable nanolayer planes embedded in insulating layers (e.g. dielectric) which, at the cross-sectional surface, act as finely spaced wires for sensing and/or controlling an adjacent spatial field.

### V. BRIEF DESCRIPTION OF THE DRAWINGS

The accompanying drawings, which are incorporated into and form a part of the disclosure, are as follows:

FIG. 1 illustrates a conventional vapor deposition method shown depositing two materials through a mask onto a substrate.

FIG. 2a is an isometric perspective view of a first deposition step of an exemplary embodiment for fabricating a thin film multilayer stack having nanolayers with tab sections extending out from the stack, and particularly showing the deposition of a first conductor nanolayer.

FIG. 2b is an isometric perspective view of a second deposition step following FIG. 2a, showing the deposition of an insulating layer over the first conductor nanolayer to leave tab sections exposed.

FIG. 2c is an isometric perspective view of a third deposition step following FIG. 2b, showing the deposition of a second conductor nanolayer over the insulating layer.

FIG. 2d is a top view of an illustrative multilayer stack formed with 14 pairs of conductor and insulating layers, using the deposition method of FIGS. 2a-c.

FIG. 3a is a top view of the multilayer stack of FIG. 2d having a division line formed (e.g. by scratching the substrate) to divide the stack into two halves therealong, and illustrating a preferred method of exposing the cross-sectional surface and the nanoscale edges.

FIG. 3b is an isometric perspective view of one of the divided halves constituting a preferred embodiment of the thin film device of the present invention.

FIG. 3c is a cross-sectional side view of the thin film device of FIG. 3b, with the vertical scale greatly exaggerated.

FIG. 4a is a top view of a second preferred embodiment of the thin film device of the present invention, showing the multilayer stack of FIG. 2d with a borehole formed therethrough so that a cross-sectional surface is formed bounding at least a section of the borehole, and illustrating a second preferred method of exposing the cross-sectional surface and the nanoscale edges.

FIG. 4b is a cross-sectional side view of the thin film device of FIG. 4a additionally having inlet and outlet conduits, and illustrating the channeling of molecules through the nanochannel for sequencing by the electrically addressable multilayer.

FIG. 4c is a cross-sectional side view of a thin film device similar to FIG. 4b except the inlet conduit serves as a nutrient rich reservoir in which a cell is shown excreting a molecule.

FIG. 5a is an isometric perspective view of a first step in an exemplary nanochannel fabrication method on a multilayer stack, which incorporates the preferential etching of oxide layers.

FIG. 5b is an isometric perspective view of a second step in the exemplary nanochannel fabrication method, following FIG. 5a.

FIG. 5c is an isometric perspective view of a third step in the exemplary nanochannel fabrication method, following FIG. 5b.

FIG. 5d is an isometric perspective view of a fourth step in the exemplary nanochannel fabrication method, following FIG. 5c.

FIG. 5e is an isometric perspective view of a fifth step in the exemplary nanochannel fabrication method, following FIG. 5d.

FIG. 5f is an isometric perspective view of sixth and seventh steps in the exemplary nanochannel fabrication method, following FIG. 5e.

FIG. 6a is an isometric perspective view of an exemplary embodiment of a thin film system of the present invention using two unit devices obliquely arranged relative to each other.

FIG. 6b is a schematic view of the projected intersections between the nanoscale edges of stack 36 and the nanoscale edges of stack 37 in FIG. 6a when projected across the spatial field between them, and showing a cell positioned in the spatial field for detection and manipulation.

FIG. 6c is a schematic view of the projected intersections between the nanoscale edges of stack 36 and the nanoscale edges of stack 37 in FIG. 6a when projected across the spatial field between them, and showing two objects positioned in the spatial field for detection and manipulation.

### VI. DETAILED DESCRIPTION

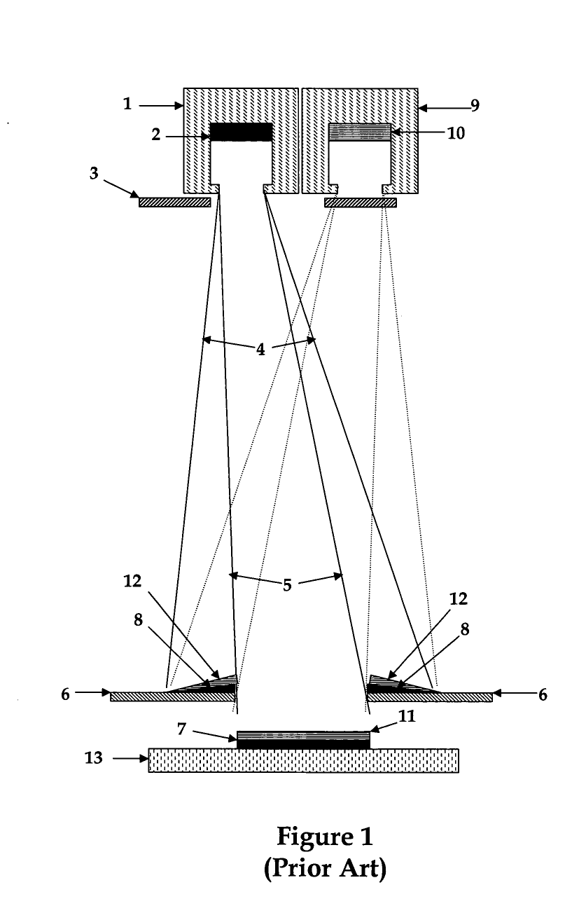

Turning now to the drawings, FIG. 1 shows a conventional vapor deposition arrangement to illustrate one exemplary technique which may be used for fabricating the multilayer stack of the present invention. In particular, FIG. 1 shows the vapor deposition of two materials, an electrically conductive material (2) and an insulating material (10), on a substrate (13) by passing the materials through an aperture of a mask (6). A first cavity (1) is shown containing material (2) and a second cavity (9) is shown containing material (10). The first cavity (1) ejects a vapor of the material (2) through the cavity opening when shutter (3) is removed from blocking the cavity opening. The material vapor expands in a beam of an extent (4) which has a sub region (5) defined by the dimensions of the aperture of the mask (6). The sub region (5) of the beam is significantly uniform in its deposition of a first layer (7) of conductive material (2) onto the substrate (13). The non-uniform layer (8) deposits on the mask (6). After a period of time, the shutter (3) moves in front of cavity (1) to block the deposition of material (2). Deposition of the insulating material (10) begins when the shutter in front of the cavity is moved to unblock that cavity's opening. A substantially uniform layer (11) of insulating material (10) is formed atop the first layer (7). And a non-uniform deposition (12) occurs on the mask (6). Alternating conductor and insulating (dielectric) layers may be deposited in this manner to form a multilayer stack.

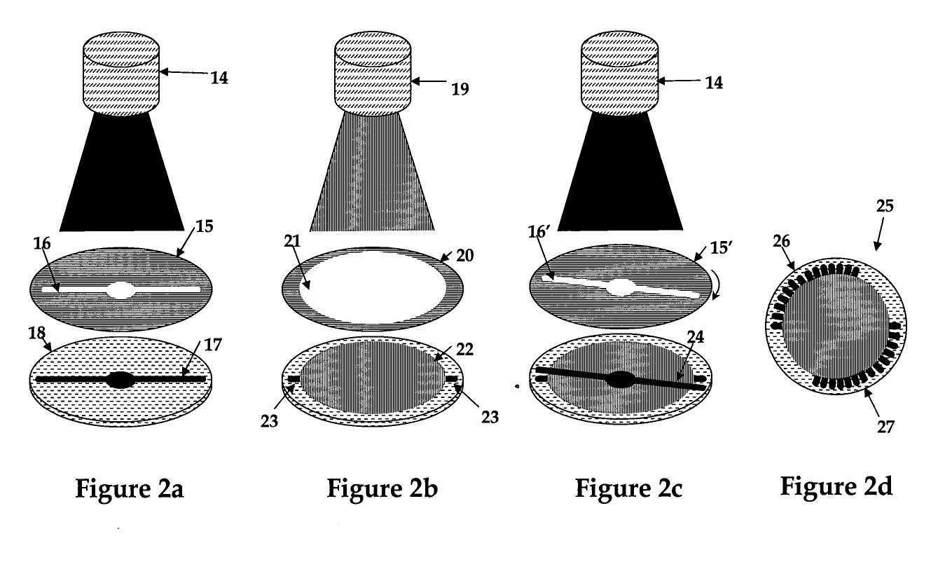

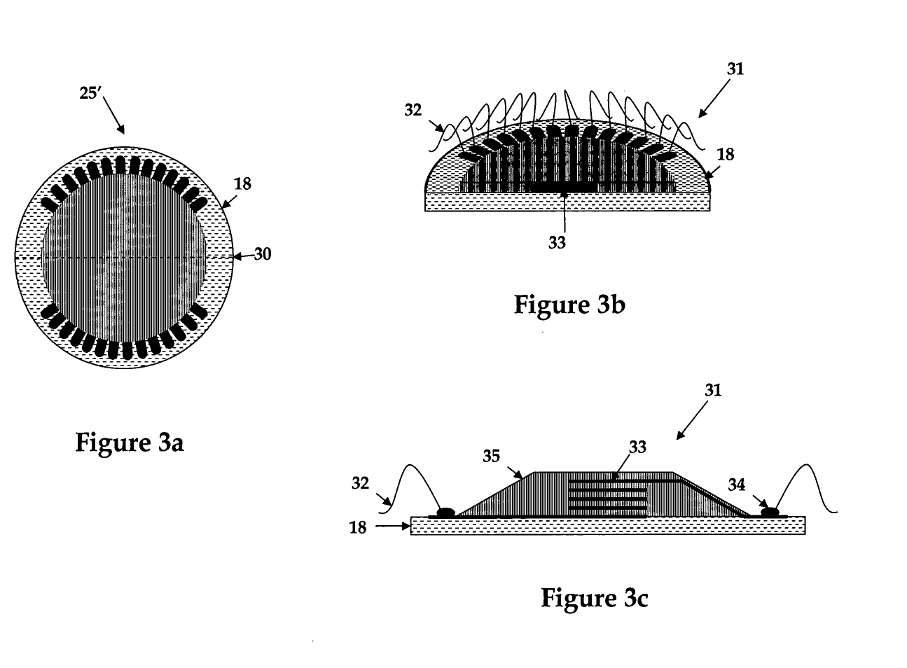

FIGS. 2a-d and 3a-c show the fabrication steps of a first preferred embodiment of the present invention having a plurality of addressable nanolayers and insulating layers which form the multilayer stack, and a planar cross-sectional surface exposing the nanoscale edges of the nanolayers. FIGS. 2a-2d together show the steps for first forming a thin film multilayer stack using a rotatable mask, and FIGS. 3a-3c show how the multilayer stack is subsequently processed to expose the planar cross-sectional surface. For illustrative purposes only, an electrically conductive material is chosen as the addressable nanolayer, and a non-conductive material is chosen as the insulating layer. While FIGS. 2a-d show the use of a rotatable mask, a plurality of masks having spatially differentiated patterns may be used instead of the spatially orientable or otherwise controllable mask, to deposition form the addressable nanolayers.

In particular, FIGS. 2a through 2c show the deposition of three layers, namely a conductor deposited through a slot (FIG. 2a), followed by a non-conducting capping layer (FIG. 2b), and followed by another conductor layer (FIG. 2c). The conductor layer deposited in FIG. 2c is preferably followed by another non-conducting capping layer (not shown), until a desired stack is formed, such as shown in FIG. 2d. The particular arrangement shown in FIGS. 2a-d is an alternating arrangement, with the first and successive odd numbered depositions using a first deposition source (14) to deposit conductor material through a slot shaped aperture (16) of a mask (15) rotated at different angles, and even number layers (such as 22) using a second deposition source (19) to deposit insulating (dielectric) material through a second aperture 21 of a second mask (20). While the apertures (15) and (20) are shown having different patterns, it is appreciated that a single pattern aperture may be used for both. And the substrate (18) used in the multilayer stack can be any suitable material known in the art for use as a substrate, including a silicon wafer such as a silicon wafer cut from a single crystal. However, the substrate is preferably of a type capable of being drilled, fractured, polished, such as for example by chemical mechanical polishing, or otherwise processed.

The mask (15) is shown in FIG. 2a at a first position, so that depositing the conductor material through the slot aperture (16) forms a first conductor nanolayer (17) on substrate (18). As shown in the figures, the slot aperture (16) can have a suitably large width that is not in the nanoscale range, e.g. it can have micron resolution or poorer. Next, the non-conductive material is deposited through a second mask (20) having an aperture (21) to form an insulating layer (22). As shown in FIG. 2b, the aperture (21) has a diameter less than the diameter of the slot aperture (15) so that tab sections (23) of the conductor nanolayer (17) extend out from the overlapping sections in the center. In FIG. 2c, the mask (15′) is shown slightly rotated to a second position so that depositing the conductor material through the aperture (16′) forms the conductor nanolayer (24). By laying down multiple pairs of conductor and insulating layers in which the slot is slightly rotated between depositions of the conductor nanolayers, electrical access to the individual conductor nanolayer is possible near the edge of the substrate (18).

It is appreciated that the rotation of the mask (15 and 15′) is about a rotation axis passing through the center of the aperture (16 and 16′) so that at least a portion of the deposited formation overlaps with other layers to form the stack. Rotating the slotted mask (15) to a new angular position in this manner allows for the next nanolayer (24) to overlap in the center but not overlap at the periphery. The overlapping sections of nanolayers and insulating layers form the multilayer stack, and non-overlapping sections form the tab sections extending out from the multilayer stack.

A top view of an illustrative multilayer stack (25) formed after depositing 14 pairs of conductor-insulating layers is shown in FIG. 2d. In particular, two tab sections are shown formed for each addressable nanolayer in the completed multilayer stack. A first group of tab sections (26) is shown formed on one side of the multilayer stack, and a second group of tab sections (27) are shown formed on the other side of the multilayer stack. The two tab sections of each nanolayer may be used to either provide two connection ports to a single multilayer stack, or created as an intermediate manufacturing step, discussed in detail below. Also, the multilayer stack may be formed to create overlapping regions that are not necessarily in the center of rotation, and the regions where thin films do not overlap are not necessarily at the periphery. For example, the rotatable mask may be configured with a circular ring aperture with inwardly pointing spoke sections that never reach the center of rotation, so that rotating the mask will maintain the position of the ring section of the aperture while repositioning the spoke sections.

Also, while the FIGS. 2a through 2d are described for making each electrically conducting nanolayer individually addressable, fewer rotation choices of the mask (15) (and consequently fewer macro tab sections/attachment points) may be provided, so that each rotation may overlap and/or contact multiple layers simultaneously. In this alternative overlapping configuration, tab sections may be overlapped or otherwise connected to form simultaneously addressable groups of nanolayers. In this case the nanolayers comprising a group are preferably not adjacent to each other. This principle may be illustrated by considering the example case of three rotations: A, B and C for 90 layer pairs. If the sequence of conductors (spaced by non-conductive regions) is ABCABCABCABC and so on, then there would be 30 A conductors, 30 B conductors and 30 C conductors perfectly shuffled into the multilayer. If each layer is of equal thickness, then a particle with dimensions of three layer pairs or less, could be moved by electrostatic forces as a voltage is moved from A to B to C to A and so on. Reversing the sequence of voltage placement from A to C to B to A and so on, would reverse the forces which act like a conveyer to move, not just one particle, but almost any number of them. Crystal growth can also be promoted by electrostatically aligning molecules such as proteins. This can aid biologists understand their structure through x-ray crystallography.

The multilayer stack formation of FIGS. 2a-d discussed above may employ a uniform deposition process, such as that described with regard to FIG. 1, to achieve uniform thickness across the span of each layer of the multilayer stack. In the alternative, a non-uniform deposition process may be used to produce layers having non-uniform thickness across their span. For example, because all addressable nanolayers preferably have their tab sections formed on the substrate, i.e. at the same level, later deposited nanolayers face an increasing vertical dimension to overcome in order to connect a tab section with its corresponding nanoscale edge, when compared to earlier deposited nanolayers. Therefore, the formation of each layer, including addressable nanolayers and insulating layers, may be deposited to have a taper or incline, such as for example a Gaussian profile, which is thinner at a periphery than at the center, so that later formed addressable layers may gradually ascend to the top of the stack by being ramped up by the slope created by the underlying stacked layers.

FIGS. 3a-3c show the next fabrication step after forming the multilayer stack (25′), which is to expose a cross-sectional surface of the multilayer stack, including exposing nanoscale edges of the addressable nanolayers. In particular, FIGS. 3a-c show how cleaving the substrate exposes an array of accessible conductors which are spaced by electrically thin insulating layers. Cleaving is achieved by first scratching the substrate (18) on the bottom so as to induce a quality fracture along the line (30) of the multilayer stack (25′) which separates the wafer and the stack into two equal halves, such as (31) in FIGS. 3b and 3c. A nanometer resolution on the resultant wires may be achieved by using this preferred technique. Chemical Mechanical Polishing (CMP) may also be useful in some cases when a good cleave is difficult to obtain. Generally, a portion of the multilayer stack may be removed by any suitable material removing process known in the art to create the cross-sectional surface, which may include any technique which physically (mechanically, chemically, electrically, electrochemically, etc) removes material, such as by cutting, cleaving, polishing, abrading, milling, machining, chemically etching, etc. The cross-sectional surface may be treated/applied with at least one surface treatment, including but not limited to preferential etching of layer edges to create roughness, voids, channels, etc., and depositing passivation layers including but not limited to using fluidic self assembly or oxide growth. In this regard, the exposed cross-sectional surface may not be smooth or planar, but rather have nanoscale edges protruding slightly from the insulating layers to create surface rougness, or be etched deeper than the surround insulating layers to form corrugations.

In any case, one section of the resulting halves (31) is shown in FIG. 3b having macrointerconnects attached to the tab sections. In particular, wires (32) may be soldered, ultrasonically wire bonded, or otherwise electrically contacted to the conductive tabs by some other means known in the art. Each tab section is shown electrically addressing one layer in the multilayer stack (33). FIG. 3c indicates an exaggerated shape of solder balls (34) and insulating material (35) in an edge on side view of the multilayer stack (33) and the thin film device (31) generally.

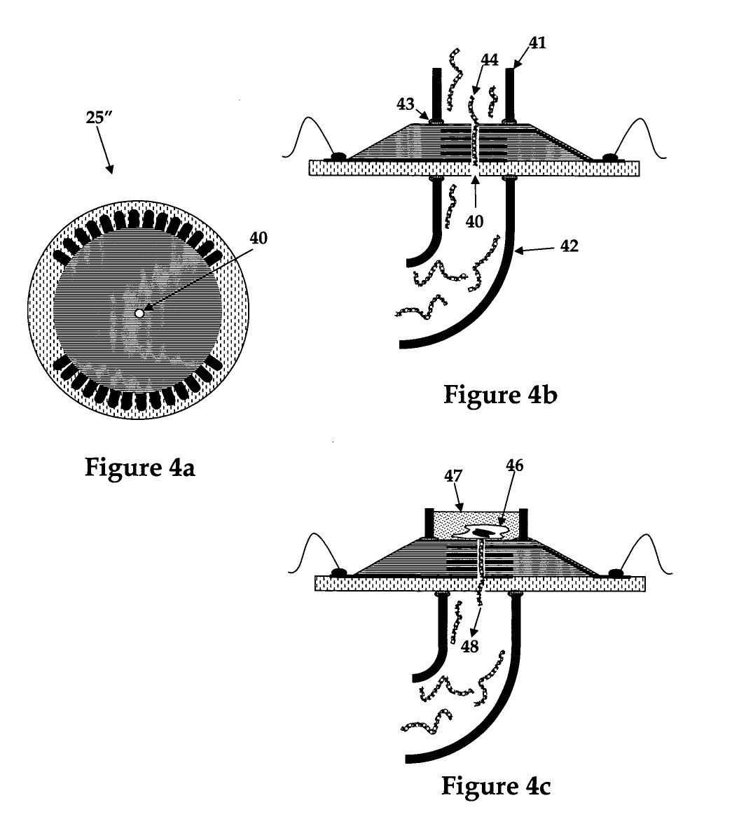

FIG. 4a shows an alternative method of exposing the cross-sectional surface of the multilayer stack and the nanoscale edges of the addressable nanolayers. Instead of cleaving, polishing, etching, or otherwise to form a planar cross-sectional surface, a borehole or pore (40) is formed through the multilayer stack (25″) to expose a curvilinear cross-sectional surface of the stack. The borehole (40) may be formed by drilling and polishing, such as by using lasers and focused electron or ion beams, but is not limited only to such.

And preferably, as shown in FIGS. 4b and 4c, fluidic conduits are provided to facilitate the passing of molecules, for example, across the multilayer cross-section. The fluidic conduits include an inlet/input conduit (41) and an output conduit (42) connected to the multilayer stack to provide fluidic communication with the borehole or pore (40). The borehole preferably has a nanoscale cross-section (i.e. a nanopore) which allows molecules to be sequenced by the electrically addressable multilayer. Molecules, such as (44) in FIG. 4b, may be DNA, amino acid chains, or other objects plumbed in through the inlet conduit (41) above the nanochannel (40) and passed out from the nanochannel into the outlet conduit (42). Glue (43) or other means may be used to connect the conduits to enable fluid handling without leakage onto the electrical contacts near the attached wires. FIG. 4d shows a cell (46) in a nutrient rich reservoir (47) which is excreting a molecule (48) which presumably could be a protein before it is properly folded.

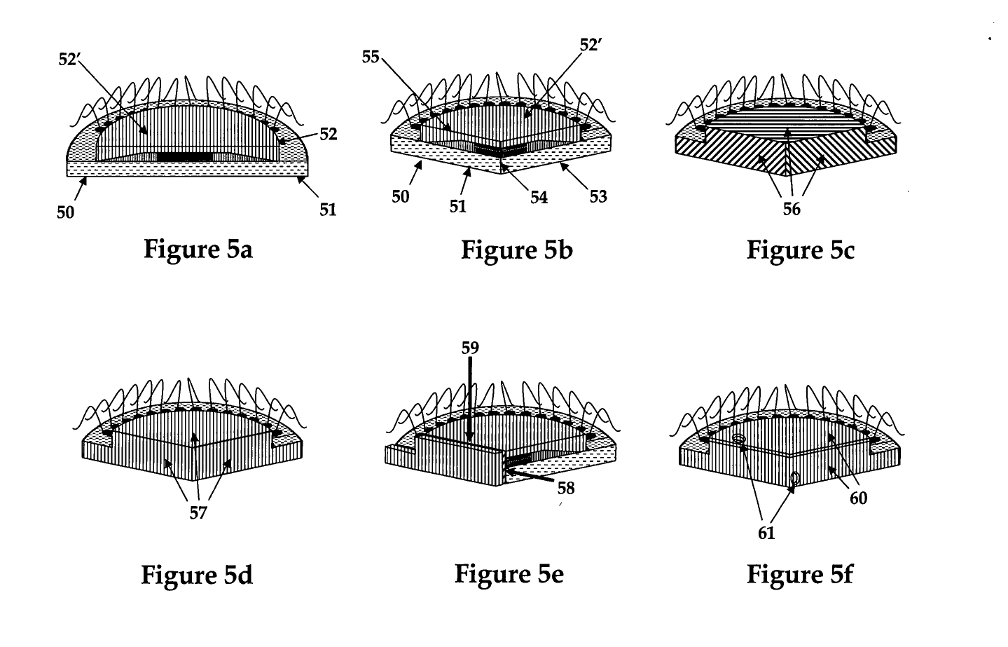

FIGS. 5a through 5f illustrate another preferred embodiment of the fabrication method of the present invention. In particular, FIGS. 5a-f show the fabrication of a nanochannel and an alternate method of directing molecules through the nanochannel and across the cross-sectional surface of the multilayer stack. Preferential etching of oxide layers is employed in this method. Starting with a halved multilayer stack (50) with a cross-sectional surface (51) (similar to the stack (31) in FIG. 3b), amorphous silicon (52) is grown atop the device. In FIG. 5b, a second cross-sectional surface (53) is formed using a technique previously described so that the first and second cross-sectional surfaces intersect at a corner edge (54). And the first cross-sectional surface 51 is shown intersecting the outer surface (52′) along a second corner edge (55). At this point, the two cross-sectional surfaces (51) and (53) may be polished, such as by chemically and mechanically polishing (CMP), prior to an oxide layer (56) being grown on at least the first cross-sectional surface, but in the alternative on all three surfaces as shown in FIG. 5c. Another layer of amorphous silicon (57) is then grown upon the oxide layer (56) as shown in FIG. 5d. In FIG. 5e, a chemical etch in the direction of arrow (58) adjacent the first corner edge (54) and also in the direction of arrow (59) adjacent the second corner edge (55), will preferentially etch the oxide layer (56) faster than the other materials and create nanometer sized corner grooves/depressions adjacent the corner edges, with the corner grooves in fluidic communication with each other. It is appreciated that the formed corner grooves are bounded in part by the first cross-sectional surface (51). Next, by applying non-conducting capping layers (60) to cap the corner grooves, a vertical nanochannel (not shown) and a horizontal nanochannel (not shown) is formed in fluidic communication with each other. FIG. 5f also shows creating ports (61) to access the nanochannels, such that molecules can be passed into the horizontal nanochannel, and down the vertical nanochannel and across the multilayer. By having many (perhaps hundreds of layers, these signals can be shifted in time and added in phase to greatly enhance the signal to noise ratio. The embodiment shown in FIG. 5f may be utilized, for example, as a molecule sequencer. It is appreciated that the process described in FIG. 5 may require the use of doping to create the conductive layers which may put limitations on layer spacing and conductivity.

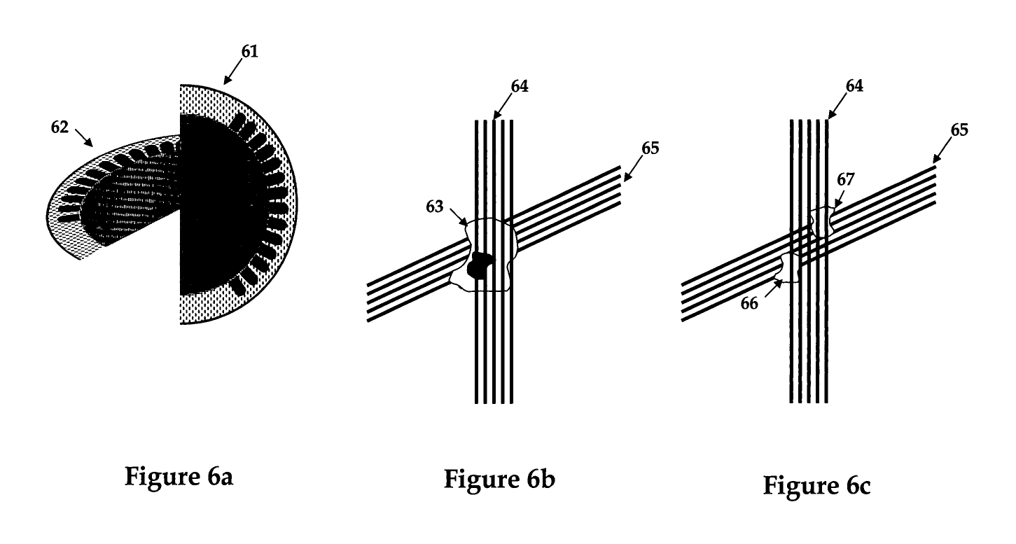

FIG. 6a-c show a preferred thin film system using the unit device of the present invention shown in FIGS. 3b and 3c. By placing two exposed multilayer systems (61 and 62) in close proximity and having them obliquely rotated with respect to one another (preferably 90° in which the edges would be perpendicular) allows for two dimensional detection (imaging) and manipulation with resolutions far below 100 nm. In particular, the two cross-sectional surfaces are spaced from each other to define a spatial field therebetween, and arranged such that the nanoscale edges are skew or otherwise non-parallel to each other. Preferably the nanoscale edges of the two cross-sectional surfaces are arranged to be orthogonally skew relative to each other to from an orthogonal grid. In any case, the skew lines of the two cross-sectional surfaces intersect each other when projected across the spatial field. Specific regions of the spatial field corresponding to the projected intersections may be sensed and/or controlled by addressing the nanoscale edges as previously described.

The arrangement of FIG. 6a may be particularly used for tracking the movement of subcomponents within cells and microorganisms for cellular imaging and interaction studies. For example, FIG. 6b shows a close up view in which a cell (63) is sandwiched between the perpendicular stacks (64) and (65). Each pixel in the array could be addressed by the unique overlap of one conductor from each stack to sense and/or control the region of the spatial field corresponding to the pixel. For imaging, one row can be excited with an electrical signal, followed by monitoring all of the columns for transmission of that signal through different parts of the cell (nucleus, cytoplasm, etc.). Advancing quickly to the next row until all the rows have been monitored allows for the build up of a 2D image. Rapid scanning in this way could provide real time (video rate) imaging of cellular activity. And FIG. 6c illustrates two objects (66 and 67) which are within the overlap region of the stacks (64) and (65). As shown in FIGS. 6b and 6c, the black lines are not wires, rather they represent the nanoscale edges of the nanolayers exposed on the two surfaces whereby electrical charges may be dynamically controlled. Control of surface charges would induce movement of charged particles (including molecules such as DNA which is negatively charged). By manipulating the surface charges, objects (66 and 67) may be moved into close proximity for purposes of assembly or to study the interactions including the binding strength required to separate objects that have an affinity for one another (like viruses and antibodies). In addition to micro and nano assembly, one could move the charges on the surface in such a way as to transfer energy to tiny machines, to act as a conveyor, or perform catalytic or enzymatic reactions. By controlling the orientation and proximity of objects (66 with respect to 67), one may be able to stimulate, increase, and/or terminate catalytic or enzymatic reactions or electrical and optical interactions, including FRET (Fluorescence Resonance Energy Transfer) which is suited to measuring distances approximating the Forster distance, which is typically 2 to 9 nanometers.

Using the present invention electrostatic forces may be controlled at the nanometer level with an array of addressable conductors on a surface. This array of wires can be charged to move, energize, excite, assemble or sense objects on or near the surface. One can imagine rolling a small conductive or charged ball or cylinder by controlling the electrostatic forces impinging upon it. In this manner of addressing between the maco and nano regimes, the thin film device and system may be used to move, sense, align and manipulate nanoscale objects including molecules. Example applications include tunable x-ray gratings and polarizers, forensic analysis, chemical and biological sensing and manipulation, catalyst reactions, gene sequencing and the assembly, motility, and energizing of MEMs (micro-electromechanical systems) and MOEMs (micro-optic electromechanical systems).

Moving and sensing a portion of DNA with the thin film device of the present invention is also possible. By changing the voltages of some of the conductors, electrostatic forces can hold and move a molecule or MEMs device while at the same time sensing with other conductors a change in resistance and capacitance as the object moves across the array of wires. Objects may be brought together in a precise way while the interactions are studied with exterior diagnostics including spectrometers. In particular, these forces may be used to bring molecules together and then try to pull them apart in order to assess the binding forces between these two molecules, as described above. The interplay of thousands of proteins in our bodies is quite difficult to predict so ex-vivo (in-vitro) methods allow us to monitor and predict activity. The present invention may therefore be used to greatly enhance diagnosis and treatment of medical problems, particularly by providing treatments that are unique to your person.

An additional use of the thin film device of the present invention is to detect direct current resistance and alternating current impedance characteristics of unknown materials between electrodes. These and other pulsed techniques can reveal dielectric constants, transient response, decay rates, polarizability, florescence and birefringence, among other material properties. More important, this invention allows the monitoring of these materials in real time and high resolution. Thus one can track the movement and chemical changes as these various molecules interact within cells or other environments.

The thin film device of the present invention could also be used, for example, in diagnostic testing of, for example, manufactured pharmaceuticals, plastics or other molecules. Also forensics could particularly benefit since crime scene quantities may be very small. This device is designed to work with extremely small samples (single molecules in fact), thus eliminating some steps (such as PCR for DNA amplification which can be problematic in it's own right). Also, biological or chemical warfare agent detection may also be possible with this device. For example, RNA of suspect organisms can be tagged to make the detection easier as it passes through the nano pore or nanochannel and across the multilayer.

The device of the present invention can also be configured as a read and/or write head for computer memories. A spinning or translating surface would be in close proximity to this read head and possibly between perpendicular conductor stacks (61) and (62) as shown in FIG. 6a. The surface would be coated with molecules or nanodevices (possibly a monolayer of bound nanospheres) that are bistable (or can hold information for at least 100 ms) and can have their information state be changed by ac or dc electric fields or currents. Reading of the data may be electrical or optical (as in the case where differences in florescence, polarization, temporal response such as decay, birefringence, interference, scattering, luminescence, or absorption is observed). To beat the optical diffraction resolution limit (say one micron), one merely needs to excite one point (such as a 5 nm by 5 nm region) electrically or attenuate all surrounding regions (such as a 1 micron by 1 micron region except one particular 5 nm by 5 nm sub region within it), and sense that entire 1 micron by 1 micron region optically. By systematically changing the excitation point, you can sequentially scan all of the 5 nm by 5 nm sub regions within that optical resolution point. A two dimensional array of optically addressable regions (perhaps by imaging a million optical points in parallel with a megapixel CCD where each pixel is registered to a 1 micron by 1 micron optical resolution point) allows for one million simultaneous reads of nanometer sized regions (in this example 5 nm by 5 nm). The high information density and throughput are possible in write mode as well since a micro display can be imaged onto the surface whose molecules or nanodevices are only sensitized or desensitized by the electrical signals from the array stacks in this invention. It also has the possibility of being fast and inexpensive.

While particular operational sequences, materials, temperatures, parameters, and particular embodiments have been described and or illustrated, such are not intended to be limiting. Modifications and changes may become apparent to those skilled in the art, and it is intended that the invention be limited only by the scope of the appended claims.

I claim:

1. A method of fabricating a thin film multilayer device, comprising:
forming a multilayer stack having a substrate, at least one addressable nanolayer, and at least one insulating layer, said stack forming step including forming each addressable nanolayer with at least one tab section extending out from the multilayer stack with a greater-than-nanoscale surface area; and
exposing a cross-sectional surface of the multilayer stack including a nanoscale edge of each addressable nanolayer, whereby a spatial field adjacent the exposed cross-sectional surface may be sensed and/or controlled by the nanolayer edge(s) in the nanoscale regime when addressed from a greater-than-nanoscale regime via the corresponding tab section(s).

2. The method of claim 1,
wherein the addressable nanolayer(s) is formed from an electrically conductive material so as to be electrically addressable from the greater-than-nanoscale regime.

3. The method of claim 1,
wherein the addressable nanolayer(s) is formed from an optically transmissive material so as to be optically addressable from the greater-than-nanoscale regime.

4. The method of claim 1,
wherein the addressable nanolayer(s) is formed with a thickness less than 100 nanometers.

5. The method of claim 1,
wherein the multilayer stack is formed with a plurality of addressable nanolayers and insulating layers which insulate the addressable nanolayers from each other.

6. The method of claim 5,
wherein the plurality of addressable nanolayers and insulating layers of the multilayer stack are deposition formed.

7. The method of claim 6,
wherein the deposition formation includes: selecting a first position for a slot of a spatially-controllable mask; depositing a first nanolayer through the slot in the first position; depositing an insulating layer on the first nanolayer leaving the corresponding tab section(s) exposed; selecting a second position of the slot of the spatially-controllable mask; depositing a second nanolayer on the insulating layer through the slot in the second position; and depositing an insulating layer on the second nanolayer leaving the corresponding tab section(s) exposed.

8. The method of claim 7,
wherein the slot position is selected by rotating the mask about an axis of rotation through the slot so that a section of the nanolayers overlap each other.

9. The method of claim 6,
wherein the deposition formation includes: selecting a first one of a plurality of masks having spatially-differentiated patterns; depositing a first nanolayer through the pattern opening of a first selected mask; depositing an insulating layer on the first nanolayer leaving the corresponding tab section(s) exposed; selecting a second one of the plurality of masks; depositing a second nanolayer on the insulating layer through the pattern opening of the second selected mask; and depositing an insulating layer on the second nanolayer leaving the corresponding tab section(s) exposed.

10. The method of claim 5,
wherein the addressable nanolayers and insulating layers are formed by selectively doping the substrate with an addressable dopant for the nanolayers and an insulating dopant for the insulating layers.

11. The method of claim 5,
wherein the plurality of addressable nanolayers and insulating layers are formed in alternating arrangement.

12. The method of claim 5,
wherein at least one group of at least two addressable nanolayers is formed so that the tab sections of each group are in contact with each other so that the nanolayers and nanoscale edges of a group are addressable together.

13. The method of claim 1,
wherein the cross-sectional surface is exposed by a removal process selected from the group consisting of cleaving, polishing, and etching.

14. The method of claim 1,
wherein the cross-sectional surface is exposed by forming a borehole through the multilayer stack.

15. The method of claim 14,
further comprising connecting an input conduit and an output conduit to the multilayer stack on opposite surfaces thereof to be in fluidic communication with the borehole.

16. The method of claim 1, further comprising:
exposing a second cross-sectional surface which intersects the first exposed cross-sectional surface along a corner edge;
forming a nanoscale first overlayer on the first exposed cross-sectional surface;
forming a second overlayer on the first overlayer;
etching the first overlayer adjacent the corner edge to produce a corner groove bounded in part by the first exposed cross-sectional surface; and
capping the corner groove with a third overlayer to form a nanochannel bounded in part by the first exposed cross-sectional surface of the multilayer stack.

17. The method of claim 16, further comprising:
additionally forming the first and second overlayers on both the second exposed cross-sectional surface, and an outer surface of the multilayer stack which intersects the first exposed cross-sectional surface along a second corner edge;
exposing the first overlayer adjacent the first and second corner edges;
additionally etching the first overlayer adjacent the second corner edge to produce a second corner groove in fluidic communication with the first corner groove;
additionally capping the second corner groove with the third overlayer to form a lead-in nanochannel in fluidic communication with the first nanochannel; and
forming an inlet port leading into the lead-in nanochannel and an outlet port leading out of the first nanochannel.

18. A thin film device fabricated according to the method of claim 1.

19. A thin film device comprising:
a thin film multilayer stack having a substrate, at least one addressable nanolayer, and at least one insulating layer, each addressable nanolayer having at least one tab section extending out from the multilayer stack with a greater-than-nanoscale surface area, and said multilayer stack having a cross-sectional surface exposing a nanoscale edge of each addressable nanolayer,
whereby a spatial field adjacent the cross-sectional surface may be sensed and/or controlled by the nanoscale edge(s) in the nanoscale regime when addressed in the greater-than-nanoscale regime via the corresponding tab section(s).

20. The thin film device of claim 19,
wherein the addressable nanolayer(s) is an electrically conductive material so as to be electrically addressable from the greater-than-nanoscale regime.

21. The thin film device of claim 19,
wherein the addressable nanolayer(s) is an optically transmissive material so as to be optically addressable from the greater-than-nanoscale regime.

22. The thin film device of claim 19,
wherein the addressable nanolayer(s) has a thickness less than 100 nanometers.

23. The thin film device of claim 19,
wherein the multilayer stack has a plurality of addressable nanolayers and insulating layers, with the addressable nanolayers insulated from each other by the insulating layers.

24. The thin film device of claim 23,
wherein the plurality of addressable nanolayers and insulating layers of the multilayer stack are deposition-formed.

25. The thin film device of claim 24,
wherein the deposition-formed addressable nanolayers have the same shape but with different orientations so that each has an overlapping section and non-overlapping tab section(s).

26. The thin film device of claim 23,
wherein the addressable nanolayers and insulating layers are doped regions of the substrate.

27. The thin film device of claim 19,
wherein the plurality of addressable nanolayers and insulating layers have an alternating arrangement.

28. The thin film device of claim 19,
wherein the multilayer stack has at least one group of at least two addressable nanolayers, with the tab sections of each group in contact with each other so that the nanolayers and nanoscale edges of a group are addressable together.

29. The thin film device of claim 19,
wherein the cross-sectional surface is a planar surface.

30. The thin film device of claim 19,
wherein the cross-sectional surface is at least a section of an inner surface of a nanochannel extending through the multilayer stack.

31. The thin film device of claim 30,
further comprising an input conduit and an output conduit connected to the multilayer stack on opposite surfaces thereof and in fluidic communication with the nanochannel.

32. The thin film device of claim 30,
further comprising a lead-in nanochannel orthogonal to and in fluidic communication with the first nanochannel; an inlet port leading into the lead-in nanochannel; and an outlet port leading out of the first nanochannel.

33. A thin film system comprising:
first and second thin film multilayer stacks, each having a substrate, at least one addressable nanolayer, and at least one insulating layer, with each addressable nanolayer having at least one tab section extending out from the corresponding multilayer stack with a greater-than-nanoscale surface area, and each multilayer stack having a cross-sectional surface exposing a nanoscale edge of each addressable nanolayer thereof, said cross-sectional surfaces being spaced from each other to form a spatial field therebetween and arranged skew to each other so that the nanoscale edges of the first cross-sectional surface intersect the nanoscale edges of the second cross-sectional surface when projected across the spatial field,
whereby regions of the spatial field corresponding to the projected intersections may be sensed and/or controlled by the nanoscale edges in the nanoscale regime when addressed in the greater-than-nanoscale regime via the corresponding tab sections.

34. The thin film system of claim 33,
wherein the nanoscale edges of the first cross-sectional surface are orthogonally skew to the nanoscale edges of the second cross-sectional surface.
